(19) United States
(12) Patent Application Publication
(10) Pub. No.: US 2025/0150046 A1
(43) Pub. Date: May 8, 2025

(54) HYBRID POWER AMPLIFIER CIRCUIT

(71) Applicant: Qorvo US, Inc., Greensboro, NC (US)

(72) Inventor: Nadim Khlat, Cugnaux (FR)

(21) Appl. No.: 18/835,241

(22) PCT Filed: Jan. 19, 2023
(86) PCT No.: PCT/US2023/060904

§ 371 Date: Aug. 1, 2024

Related U.S. Application Data
(60) Provisional application No. 63/305,829, filed on Feb. 2, 2022.

(51) Int. Cl. H03F 3/24

(52) U.S. Cl. CPC H03F 3/245; H03F 2200/451

(57) ABSTRACT

A hybrid power amplifier circuit is provided. The hybrid power amplifier circuit includes a carrier amplifier and a peak amplifier configured to collectively amplify a radio frequency (RF) signal from a time-variant input power to a time-variant output power based on an envelope tracking (ET) modulated voltage. A control circuit is provided in the hybrid power amplifier circuit to bias the peak amplifier based on a reference voltage (e.g., a battery voltage) to present a modulated load impedance to the carrier amplifier to thereby cause the carrier amplifier to operate in compression in response to an average of the ET modulated voltage being substantially equal to the reference voltage. By using the ET modulated voltage to cause the carrier amplifier to operate in compression, it is possible to improve efficiency of the carrier amplifier and the hybrid power amplifier circuit as a whole.

### RELATED APPLICATIONS

This application claims the benefit of U.S. provisional patent application Ser. No. 63/305,829, filed on Feb. 2, 2022, the disclosure of which is hereby incorporated herein by reference in its entirety.

### FIELD OF THE DISCLOSURE

The technology of the disclosure relates generally to a power amplifier circuit in a power management circuit.

### BACKGROUND

The fifth generation (5G) system has been widely regarded as the next generation wireless communication system beyond the current third generation (3G) and fourth generation (4G) systems. In this regard, a 5G-capable wireless communication device is expected to achieve higher data rates, improved coverage range, enhanced signaling efficiency, and reduced latency.

The 5G-capable wireless communication device typically includes multiple transmitters to simultaneously transmit multiple 5G radio frequency (RF) signals under such schemes as Carrier Aggregation (CA) and Evolved-Universal Terrestrial Radio Access (E-UTRA) New Radio (NR) Dual Connectivity (DC) (ENDC). Since the transmitters typically transmit the 5G RF signals in a millimeter wave spectrum, the RF signals can be more susceptible to propagation attenuation and interference. To help mitigate propagation attenuation and maintain desirable data throughput, the 5G-capable wireless communication device typically employs multiple power amplifiers to amplify the RF signals to desired power levels before transmitting the RF signals from the transmitters. As such, it is desirable to ensure that the power amplifiers can operate with optimal efficiency, especially when the RF signals are transmitted with different peak-to-average ratios (PARs).

### SUMMARY

Embodiments of the disclosure relate to a hybrid power amplifier circuit. The hybrid power amplifier circuit includes a carrier amplifier and a peak amplifier coupled in parallel between a signal input and a signal output of the hybrid power amplifier circuit. In examples disclosed herein, the carrier amplifier and the peak amplifier are configured to collectively amplify a radio frequency (RF) signal from a time-variant input power to a time-variant output power based on an envelope tracking (ET) modulated voltage. A control circuit is provided in the hybrid power amplifier circuit to bias the peak amplifier based on a reference voltage (e.g., a battery voltage) to present a modulated load impedance to the carrier amplifier to thereby cause the carrier amplifier to operate in compression in response to an average of the ET modulated voltage being substantially equal to the reference voltage. By using the ET modulated voltage to cause the carrier amplifier to operate in compression, it is possible to improve efficiency of the carrier amplifier and the hybrid power amplifier circuit as a whole.

In one aspect, a hybrid power amplifier circuit is provided. The hybrid power amplifier circuit includes a signal input that receives an RF signal having a time-variant input power. The hybrid power amplifier circuit also includes a signal output that outputs the RF signal having a time-variant output power to a load circuit having an inherent load impedance. The hybrid power amplifier circuit also includes a carrier amplifier and a peak amplifier coupled in parallel between the signal input and the signal output. The carrier amplifier and the peak amplifier are configured to collectively amplify the RF signal from the time-variant input power to the time-variant output power based on an ET modulated voltage. The hybrid power amplifier circuit also includes a control circuit. The control circuit is configured to bias the peak amplifier based on a reference voltage to present a modulated load impedance to the carrier amplifier to thereby cause the carrier amplifier to operate in compression in response to an average of the ET modulated voltage being substantially equal to the reference voltage.

In another aspect, a power management circuit is provided. The power management circuit includes an ET integrated circuit (ETIC). The ETIC includes a switcher circuit. The switcher circuit is configured to generate a low-frequency current as a function of a battery voltage. The ETIC also includes a voltage circuit. The voltage circuit is configured to generate an ET modulated voltage based on an ET target voltage and the low-frequency current. The power management circuit also includes a hybrid power amplifier circuit. The hybrid power amplifier circuit includes a signal input that receives an RF signal having a time-variant input power. The hybrid power amplifier circuit also includes a signal output that outputs the RF signal having a time-variant output power to a load circuit having an inherent load impedance. The hybrid power amplifier circuit also includes a carrier amplifier and a peak amplifier coupled in parallel between the signal input and the signal output. The carrier amplifier and the peak amplifier are configured to collectively amplify the RF signal from the time-variant input power to the time-variant output power based on the ET modulated voltage. The hybrid power amplifier circuit also includes a control circuit. The control circuit is configured to bias the peak amplifier based on a reference voltage that corresponds to a reading of the battery voltage to present a modulated load impedance to the carrier amplifier to thereby cause the carrier amplifier to operate in compression in response to an average of the ET modulated voltage being substantially equal to the reference voltage.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1A is a schematic diagram of an exemplary power amplifier configured to amplify a radio frequency (RF) signal from an input power to an output power based on a modulated voltage;

FIG. 1B is a graphic diagram of an exemplary power curve that illustrates a relationship between the output power and the modulated voltage in FIG. 1A;

FIG. 2A is a schematic diagram of an exemplary hybrid power amplifier circuit configured according to an embodiment of the present disclosure to amplify an RF signal from a time-variant input voltage to a time-variant output power based on an envelope tracking (ET) modulated voltage and a modulated load impedance;

FIG. 2B is a graphic diagram of an exemplary power curve that illustrates a relationship between the time-variant output power and the modulated voltage in FIG. 2A;

FIG. 3 is a schematic diagram illustrating an exemplary equivalent electrical model of the hybrid power amplifier circuit in FIG. 2A;

FIG. 4 is a schematic diagram of an exemplary power management circuit that incorporates the hybrid power amplifier circuit in FIG. 2A; and

FIG. 5 is a schematic diagram of an exemplary user element wherein the power management circuit of FIG. 4 can be provided.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments of the disclosure relate to a hybrid power amplifier circuit. The hybrid power amplifier circuit includes a carrier amplifier and a peak amplifier coupled in parallel between a signal input and a signal output of the hybrid power amplifier circuit. In examples disclosed herein, the carrier amplifier and the peak amplifier are configured to collectively amplify a radio frequency (RF) signal from a time-variant input power to a time-variant output power based on an envelope tracking (ET) modulated voltage. A control circuit is provided in the hybrid power amplifier circuit to bias the peak amplifier based on a reference voltage (e.g., a battery voltage) to present a modulated load impedance to the carrier amplifier to thereby cause the carrier amplifier to operate in compression in response to an average of the ET modulated voltage being substantially equal to the reference voltage. By using the ET modulated voltage to cause the carrier amplifier to operate in compression, it is possible to improve efficiency of the carrier amplifier and the hybrid power amplifier circuit as a whole.

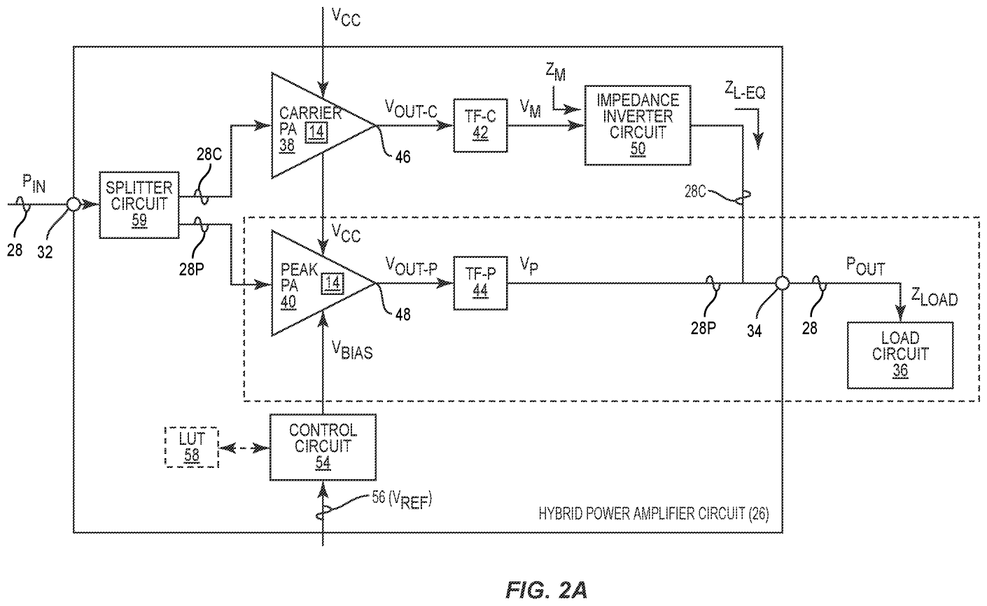

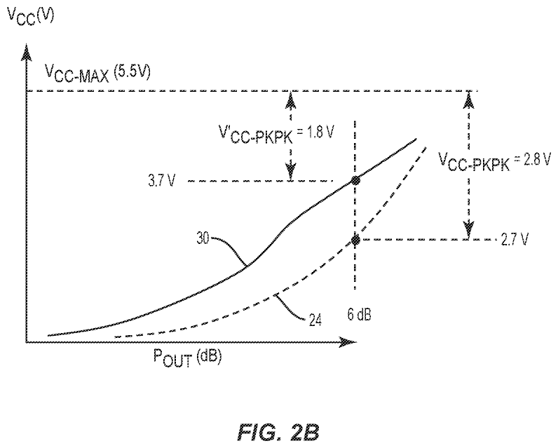

Before discussing the hybrid power amplifier circuit according to the present disclosure, starting at FIG. 2A, an overview of an exemplary power amplifier circuit is first provided to help understand various factors that may affect operating efficiency of the power amplifier.

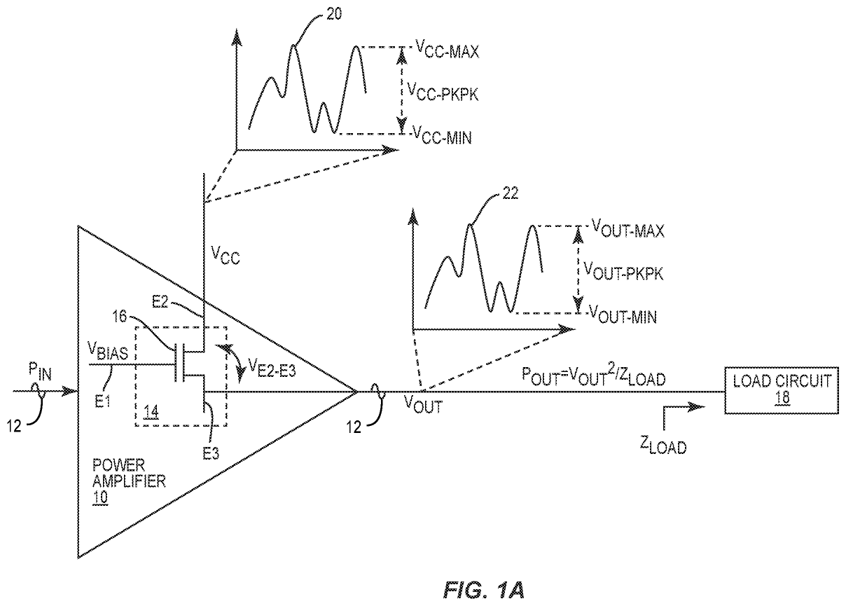

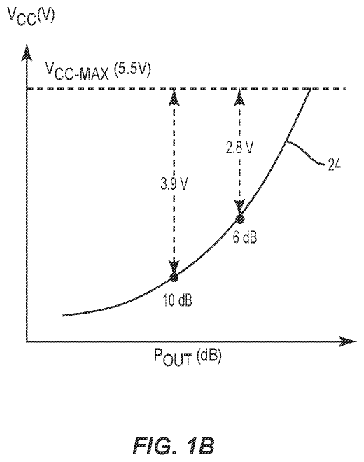

FIG. 1A is a schematic diagram of an exemplary power amplifier 10 configured to amplify an RF signal 12 from an input power PIN to an output power Pour based on a modulated voltage V_{CC}. The power amplifier 10 includes an output stage 14, which can include at least one transistor 16, as a non-limiting example. The transistor 16 includes a first electrode E1, a second electrode E2, and a third electrode E3, which may be named differently depending on a type of the transistor 16. For example, if the transistor 16 is a bipolar junction transistor (BJT), then the first electrode E1, the second electrode E2, and the third electrode E3 will be referred to as a base electrode, a collector electrode, and an emitter electrode, respectively. In contrast, if the transistor 16 is a complementary metal-oxide semiconductor (CMOS) transistor, the first electrode E1, the second electrode E2, and the third electrode E3 will be referred to as a gate electrode, a source electrode, and a drain electrode, respectively.

Herein, the first electrode E1 is configured to receive a bias voltage V_{BIAS}, the second electrode E2 is configured to receive the modulated voltage V_{CC}, and the third electrode E3 is configured to output the amplified RF signal 12 to a load circuit 18 (e.g., a transmitter circuit) at the output power POUT, which can be expressed in the equation (Eq. 1) below.

$${P}_{OUT} = {V}_{OUT}^{2} / {Z}_{L O A D} \qquad ( Eq . 1 )$$

In the equation (Eq. 1) above, V_{OUT} represents an output voltage of the amplified RF signal 12 and Z_{LOAD} represents a load impedance of the load circuit 18. The output voltage V_{OUT}, on the other hand, is proportionally related to the modulated voltage V_{CC}, as illustrated in the equation (Eq. 2) below.

$${V}_{OUT} = {V}_{CC} - {V}_{E 2 - E 3} \qquad ( Eq . 2 )$$

In the equation (Eq. 2), V_{E2-E3} represents a voltage drop between the second electrode E2 and the third electrode E3. From equation (Eq. 2), it can be seen that the output voltage V_{OUT} will be substantially equal to the modulated voltage V_{CC} if the voltage drop V_{E2-E3} is reduced to, for example, a saturation voltage (e.g., 0.3 V) of the transistor 16. Under such condition, the power amplifier 10 will operate in compression with an improved efficiency. Based on the equations (Eq. 1 and Eq. 2) and given that the output voltage V_{OUT} is substantially equal to the modulated voltage V_{CC} during compression, the output power Pour can be further expressed in the equation (Eq. 3) below.

$${P}_{OUT} = {( {V}_{CC} - {V}_{E 2 - E 3} )}^{2} / {Z}_{L O A D} \approx {V}_{CC}^{2} / {Z}_{LOAD} \qquad ( Eq . 3 )$$

The modulated voltage V_{CC} is associated with a time-variant modulated voltage envelope 20, which varies over time between a maximum modulated voltage V_{CC-MAX} and a minimum modulated voltage V_{CC-MIN}. The difference between the maximum modulated voltage V_{CC-MAX} and the minimum modulated voltage V_{CC-MIN} is known as a peak-to-peak modulated voltage V_{CC-PKPK}. Similarly, the output voltage V_{OUT} is associated with a time-variant output voltage envelope 22, which varies over time between a maximum output voltage V_{OUT-MAX} and a minimum output voltage V_{OUT-MIN}. The difference between the maximum output voltage V_{OUT-MAX} and the minimum output voltage V_{OUT-MIN} is known as a peak-to-peak output voltage V_{OUT-PKPK}. When the power amplifier 10 operates in compression, the time-variant output voltage envelope 22 will be substantially similar to the time-variant modulated voltage envelope 20. Accordingly, the peak-to-peak output voltage V_{OUT-PKPK} will be substantially equal to the peak-to-peak modulated voltage V_{CC-PKPK}.

In a conventional linear power amplifier, the load impedance Z_{LOAD} is kept constant. As such, based on the equation (Eq. 3), the output power Pour is primarily driven by the modulated voltage V_{CC}. FIG. 1B is a graphic diagram of an exemplary power curve 24 that illustrates a relationship between the output power Pour and the modulated voltage V_{CC} as expressed in the equation (Eq. 3). As shown in FIG. 1B, a magnitude of the peak-to-peak modulated voltage V_{CC-PKPK} is a function of peak-to-average ratio (PAR) of the RF signal 12. In other words, the peak-to-peak modulated voltage V_{CC-PKPK} must be sufficiently large to avoid amplitude distortion when the output power Pour peaks. For example, the peak-to-peak modulated voltage V_{CC-PKPK} is 3.9 V when the PAR is 10 dB and 2.8 V when the PAR is 6 dB. However, a larger peak-to-peak modulated voltage V_{CC-PKPK} can reduce the efficiency of the power amplifier 10, especially when the output power Pour is off-peak. In this regard, it is desirable to reduce the peak-to-peak modulated voltage V_{CC-PKPK} to help improve the efficiency of the power amplifier 10.

In this regard, FIG. 2A is a schematic diagram of an exemplary hybrid power amplifier circuit 26 configured according to embodiments of the present disclosure to amplify an RF signal 28 from a time-variant input power PIN to a time-variant output power Pour based on an ET modulated voltage V_{CC} and a modulated load impedance Z_{M}. As described in detail below, the hybrid power amplifier circuit 26 is configured not only to operate in compression based on the ET modulated voltage V_{CC}, but also to reduce a peak-to-peak range of the ET modulated voltage V_{CC} based on the modulated load impedance Z_{M}. As an example, according to the equation (Eq. 3), the hybrid power amplifier circuit 26 can handle a larger peak of the time-variant output power Pour by reducing both the ET modulated voltage V_{CC} and the modulated load impedance Z_{M}. In one aspect, by reducing the modulated load impedance Z_{M}, it is possible to reduce the peak-to-peak range of the ET modulated voltage V_{CC}. In another aspect, by reducing the ET modulated voltage V_{CC}, it is possible to cause the hybrid power amplifier circuit 26 to operate in compression. As a result, the hybrid power amplifier circuit 26 can amplify the RF signal 28 to the time-variant output power Pour with an improved efficiency.

FIG. 2B is a graphic diagram of an exemplary power curve 30 that illustrates a relationship between the time-variant output power Pour and the modulated voltage V_{CC} in FIG. 2A. As shown by the power curve 30, when the PAR of the RF signal 28 is at 6 dB, for example, the peak-to-peak range (denoted as “V′_{CC-PKPK}”) is lower than the peak-to-peak modulated voltage V_{CC-PKPK} as previously shown in the power curve 24 of FIG. 1B.

With reference back to FIG. 2A, the hybrid power amplifier circuit 26 includes a signal input 32 that receives the RF signal 28. The hybrid power amplifier circuit 26 also includes a signal output 34 that outputs the amplified RF signal 28 to a load circuit 36 (e.g., a transmitter circuit).

In an embodiment, the hybrid power amplifier circuit 26 includes a carrier amplifier 38 (denoted as “carrier PA”) and a peak amplifier 40 (denoted as “peak PA”). The carrier amplifier 38 and the peak amplifier 40, which are coupled in parallel between the signal input 32 and the signal output 34, are configured to collectively amplify the RF signal 28 from the time-variant input power PIN to the time-variant output power POUT.

In a non-limiting example, each of the carrier amplifier 38 and the peak amplifier 40 can be identical or functionally equivalent to the power amplifier 10 in FIG. 1A. In this regard, the carrier amplifier 38 and the peak amplifier 40 can each include the output stage 14 in FIG. 1A. Accordingly, the carrier amplifier 38 receives the ET modulated voltage V_{CC} via the second electrode E2 in the respective output stage 14 and outputs a carrier output voltage V_{OUT-C} via the third electrode E3 in the respective output stage 14. Likewise, the peak amplifier 40 receives the ET modulated voltage V_{CC} via the second electrode E2 in the respective output stage 14 and outputs a peak output voltage V_{OUT-P} via the third electrode E3 in the respective output stage 14.

The hybrid power amplifier circuit 26 includes a carrier load-line transfer function (TF) circuit 42 (denoted as “TF-C”) and a peak load-line TF circuit 44 (denoted as “TF-P”). The carrier load-line TF circuit 42 is coupled to an output 46 (e.g., the third electrode E3 in the respective output stage 14) of the carrier amplifier 38 and the peak load-line TF circuit 44 is coupled to an output 48 (e.g., the third electrode E3 in the respective output stage 14) of the peak amplifier 40.

The hybrid power amplifier circuit 26 also includes an impedance inverter circuit 50 that is coupled between the carrier load-line TF circuit 42 and the peak load-line TF circuit 44. The impedance inverter circuit 50 is configured to create the modulated load impedance Z_{M} based on an equivalent load impedance Z_{L-EQ}. Herein, the equivalent load impedance Z_{L-EQ} represents a total impedance presented to the impedance inverter circuit 50 by the load circuit 36, the peak load-line TF circuit 44, and the peak amplifier 40.

In an embodiment, the carrier amplifier 38 is always active regardless of the time-variant output power Pour. In contrast, the peak amplifier 40 is only activated when the time-variant output power Pour is above a certain level. In the embodiment herein, the peak amplifier 40 is activated before the carrier amplifier 38 runs into compression. In this regard, the hybrid power amplifier circuit 26 is different from a conventional Doherty power amplifier, wherein a peak amplifier is not activated until a carrier amplifier runs into compression.

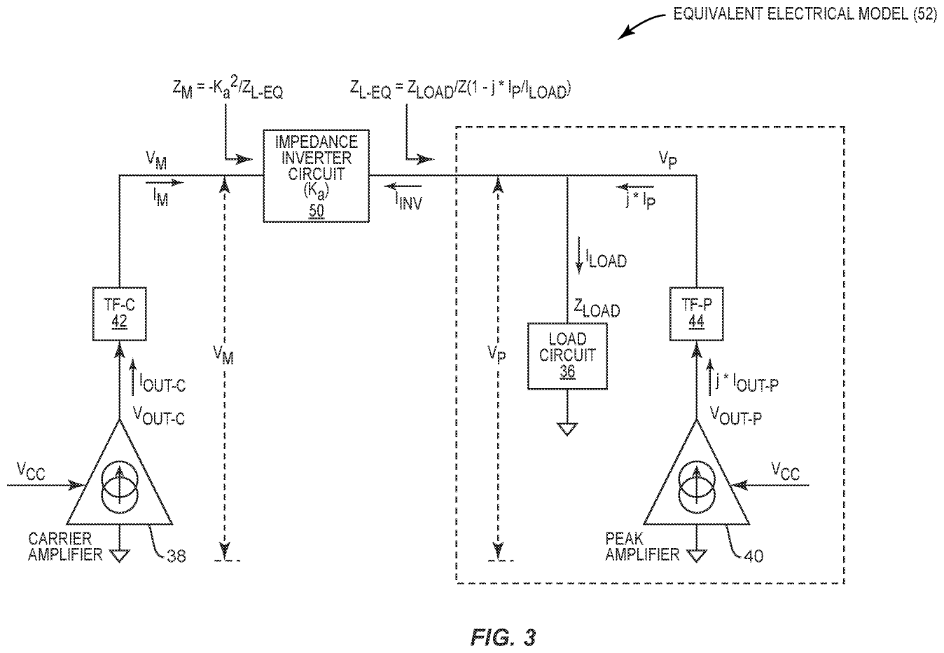

The operational theory and principle behind the hybrid power amplifier circuit 26 can be better explained based on an equivalent electrical model. In this regard, FIG. 3 is a schematic diagram illustrating an exemplary equivalent electrical model 52 of the hybrid power amplifier circuit 26 in FIG. 2A. Common elements between FIGS. 2A and 3 are shown therein with common element numbers and will not be re-described herein.

In addition to the carrier output voltage V_{OUT-C}, the carrier amplifier 38 also produces a carrier output current I_{OUT-C}. Likewise, the peak amplifier 40 also produces a peak output current/*I_{OUT-P} in addition to the peak output voltage V_{OUT-P}. As shown in the equations (Eq. 4 and Eq. 5), the carrier load-line TF circuit 42 transforms the carrier output voltage V_{OUT-C} and the carrier output current I_{OUT-C} into a time-variant carrier voltage envelope V_{M} and a time-variant carrier current envelope I_{M}, respectively. Further, as shown in the equations (Eq. 6 and Eq. 7), the peak load-line TF circuit 44 transforms the carrier output voltage V_{OUT-P} and the carrier output current j*I_{OUT-P} into a time-variant peak voltage envelope V_{P} and a time-variant peak current envelope j*I_{P}, respectively.

$${V}_{M} = {V}_{OUT - C} * TFC \qquad ( Eq . 4 )$$

$${I}_{M} = {I}_{OUT - C} / TFC \qquad ( Eq . 5 )$$

$${V}_{P} = {V}_{OUT - P} * TFP \qquad ( Eq . 6 )$$

$$j * {I}_{P} = j * {I}_{OUT - P} / TFP \qquad ( Eq . 7 )$$

In the equations above, TFC represents a carrier load-line transfer function implemented by the carrier load-line TF circuit 42 and TFP represents a peak load-line transfer function implemented by the peak load-line TF circuit 44. A relationship between the time-variant peak voltage envelope V_{P} and the time-variant carrier current envelope I_{M} can be expressed in the equation (Eq. 8) below.

$${V}_{P} = {K}_{a} * {I}_{M} \qquad ( Eq . 8 )$$

In the equation (Eq. 8), Kₐ represents a coefficient of the impedance inverter circuit 50. The equivalent load impedance Z_{L-EQ}, which represents the total impedance of the load circuit 36, the peak load-line TF circuit 44, and the peak amplifier 40, can be expressed as in the equation (Eq. 9) below.

$${Z}_{L - EQ} = {Z}_{L O A D} / ( 1 - j * {I}_{P} / {I}_{LOAD} ) \qquad ( Eq . 9 )$$

In the above equation (Eq. 9), Z_{LOAD} represents an inherent load impedance Z_{LOAD} of the load circuit 36 and I_{LOAD} represents a load current in the load circuit 36. From the equation (Eq. 9), it can be seen that when j*I_{P}=0, which is an indication that the peak amplifier 40 is deactivated, the equivalent load impedance Z_{L-EQ} will only include the inherent load impedance Z_{LOAD}. However, when j*I_{P}=½ Z_{LOAD}, for example, the equivalent load impedance Z_{L-EQ} will change to 2*Z_{LOAD}. In this regard, the equivalent load impedance Z_{L-EQ} will increase when the peak amplifier 40 is activated.

The impedance inverter circuit 50 is configured to convert the equivalent load impedance Z_{L-EQ} into the modulated load impedance Z_{M} in accordance with the equation (Eq. 10) below.

$${Z}_{M} = - {K}_{a}^{2} / {Z}_{L - EQ} = - {K}_{a}^{2} * ( 1 - j * {I}_{P} / {I}_{LOAD} ) / {Z}_{LOAD} \qquad ( Eq . 10 )$$

From the equation (Eq. 10), it can be seen that the modulated load impedance Z_{M} will decrease when the equivalent load impedance Z_{L-EQ} increases. In this regard, it is possible to reduce the modulated load impedance Z_{M} by activating the peak amplifier 40.

The time-variant carrier voltage envelope V_{M} can be determined based on the equation (Eq. 11) below.

$${V}_{M} = 4 * {Z}_{LOAD} * ( {I}_{M} - \frac{1}{2} {I}_{P} ) \qquad ( Eq . 11 )$$

A pair of derivative equations can be derived from the equation (Eq. 11), which are expressed below in equations (Eq. 12 and Eq. 13).

$${Δ V}_{M} = 4 * {Z}_{LOAD} * ( Δ {I}_{M} - \frac{1}{2} Δ {I}_{P} ) \qquad ( Eq . 12 )$$

$$avg ( {V}_{M} ) = 4 * {Z}_{LOAD} * ( avg ( {I}_{M} ) - \frac{1}{2} avg ( {I}_{P} ) ) \qquad ( Eq . 13 )$$

In the equation (Eq. 12), ΔV_{M}, ΔI_{M}, and ΔI_{P} represent a change in the time-variant carrier voltage envelope V_{M}, a change in the time-variant carrier current envelope I_{M}, and a change in the time-variant peak current envelope I_{P}, respectively. In the equation (Eq. 13), avg(V_{M}), avg(I_{M}), and avg(I_{P}) represent an average of the time-variant carrier voltage envelope V_{M}, an average of the time-variant carrier current envelope I_{M}, and an average of the time-variant peak current envelope I_{P}, respectively.

When ΔI_{P}<2ΔI_{M}, ΔV_{M} will be greater than zero. In this regard, the time-variant carrier voltage envelope V_{M} is increasing, but at a lower rate (as illustrated by the power curve 30 in FIG. 2B). According to previous discussions in FIG. 1A, when the carrier amplifier 38 operates in compression, the ET modulated voltage V_{CC} will be substantially equal to the carrier output voltage V_{OUT-C}(V_{CC}≈V_{OUT-C}). Thus, the ET modulated voltage V_{CC} can be related to the time-variant carrier voltage envelope V_{M} in the equation (Eq. 14) below based on the equations (Eq. 2 and Eq. 4).

$${V}_{CC} = {V}_{OUT - C} + {V}_{E 2 - E 3} = {V}_{M} / TFC \qquad ( Eq . 14 )$$

Further, a set of relationships between the ET modulated voltage V_{CC} and the time-variant carrier voltage envelope V_{M} can be established in the equations (Eq. 15 and 16) below based on the equations (Eq. 12-14). Accordingly, the ET modulated voltage V_{CC} can be generated to track the time-variant carrier voltage envelope V_{M} with a reduced peak-to-peak range to drive the carrier amplifier 38 into compression.

$${Δ V}_{CC} = 4 * {Z}_{LOAD} * ( Δ {I}_{M} - \frac{1}{2} Δ {I}_{P} ) / TFC \qquad ( Eq . 15 )$$

$$avg ( {V}_{CC} ) = 4 * {Z}_{LOAD} * ( avg ( {I}_{M} ) - \frac{1}{2} avg ( {I}_{P} ) ) / TFC \qquad ( Eq . 16 )$$

With reference back to FIG. 2A, the hybrid power amplifier circuit 26, can be a field-programmable gate array (FPGA), as an example. In an embodiment, the control circuit 54 can be configured to bias the peak amplifier 40 based on a reference voltage VREF that may be provided (e.g., by a transceiver circuit) in a voltage indication signal 56. Accordingly, the control circuit 54 can determine a bias voltage V_{BIAS} to bias the peak amplifier to generate the peak output current j*I_{OUT-P} at an appropriate level to thereby present the modulated load impedance Z_{M} to the carrier amplifier 38 and cause the carrier amplifier 38 to operate in compression in response to the average of the ET modulated voltage avg(V_{CC}) being substantially equal to the reference voltage VREF. Herein, the average of the ET modulated voltage avg(V_{CC}) is said to be substantially equal to the reference voltage VREF when VREF-avg(V_{CC})≤+0.05 V.

In an embodiment, the hybrid power amplifier circuit 26 can include a bias lookup table (LUT) 58 that correlates different levels of the reference voltage VREF with different levels of the bias voltage V_{BIAS}. In this regard, the control circuit 54 may retrieve an appropriate bias voltage V_{BIAS} based on the reference voltage VREF received via the voltage indication signal 56 and apply the retrieved bias voltage V_{BIAS} to the peak amplifier 40.

The hybrid power amplifier circuit 26 can include a splitter circuit 59 that is coupled to the signal input 32. In an embodiment, the splitter circuit 59 splits the RF signal 28 into a carrier RF signal 28C and a peak RF signal 28P. The carrier RF signal 28C and the peak RF signal 28P are amplified respectively by the carrier amplifier 38 and the peak amplifier 40 and then recombined into the RF signal 28 at the signal output 34.

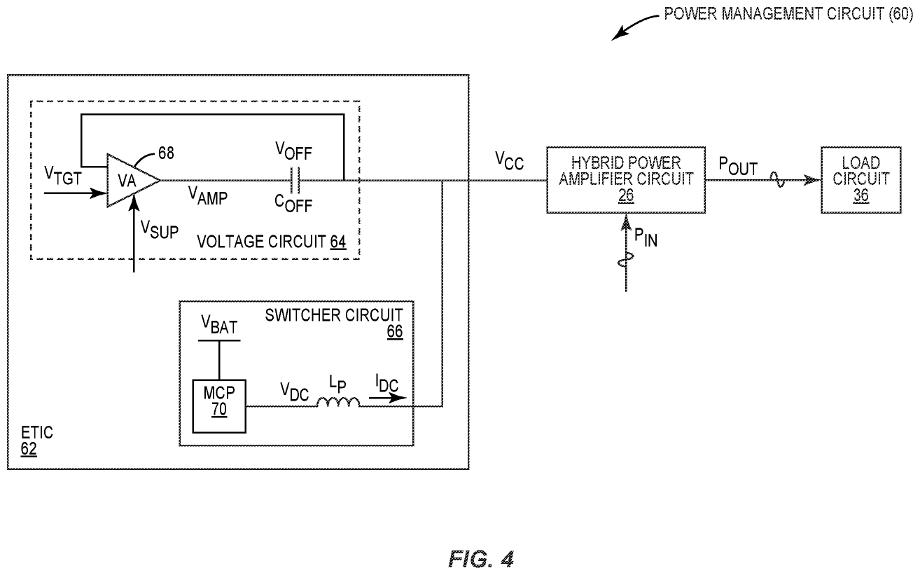

In an embodiment, the ET modulated voltage V_{CC} can be generated in an ET integrated circuit (ETIC) based on a battery voltage and the reference voltage VREF can correspond to a reading of the battery voltage. In this regard, FIG. 4 is a schematic diagram of an exemplary power management circuit 60 that incorporates the hybrid power amplifier circuit 26 in FIG. 2A. Common elements between FIGS. 2A and 4 are shown therein with common element numbers and will not be re-described herein.

The power management circuit 60 includes an ETIC 62. The ETIC 62 includes a voltage circuit 64 and a switcher circuit 66. The voltage circuit 64 includes a voltage amplifier 68 (denoted as “VA”) coupled in series with an offset capacitor C_{OFF}. The voltage amplifier 68 is configured to generate an initial ET modulated voltage V_{AMP} based on an ET target voltage V_{TGT} and a supply voltage V_{SUP}. In an embodiment, the ET target voltage V_{TGT} tracks the time-variant carrier voltage envelope V_{M} in the hybrid power amplifier circuit 26. Accordingly, the voltage amplifier 68 can generate the initial ET modulated voltage V_{AMP} to also track the time-variant carrier voltage envelope V_{M}. The offset capacitor C_{OFF} is configured to raise the initial ET modulated voltage V_{AMP} by an offset voltage V_{OFF} to generate the ET modulated voltage V_{CC} (V_{CC}=V_{AMP}+V_{OFF}). In this embodiment, the offset voltage V_{OFF} is a constant voltage (e.g., 0.8 V). As a result, the ET modulated voltage V_{CC} also tracks the time-variant carrier voltage envelope V_{M}.

The switcher circuit 66 includes a multi-level charge pump (MCP) 70, which can be a direct-current (DC)-to-DC (DC-DC) buck-boost converter, as an example. The MCP 70 is configured to generate a low-frequency voltage V_{DC} at multiple levels based on a battery voltage V_{BAT}. In a non-limiting example, the MCP 70 can operate in a buck mode to generate the low-frequency voltage V_{DC} at 0×V_{BAT} or 1×V_{BAT}, or in a boost mode to generate the low-frequency voltage V_{DC} at 2×V_{BAT}. The MCP 70 is coupled in series to a power inductor L_{P}, which is configured to induce a low-frequency current I_{DC} based on the low-frequency voltage V_{DC}. In an embodiment, the low-frequency current I_{DC} can be used to modulate the offset voltage V_{OFF} across the offset capacitor C_{OFF}.

In an embodiment, the control circuit 54 in the hybrid power amplifier circuit 26 receives the voltage indication signal 56 that indicates a reading of the battery voltage V_{BAT}. Accordingly, the control circuit 54 retrieves an appropriate bias voltage V_{BIAS} from the bias LUT 58 to bias the peak amplifier 40. As such, the carrier amplifier 38 will operate in compression, and therefore with a higher efficiency, when the average of the ET modulated voltage avg(V_{CC}) is substantially equal to the battery voltage V_{BAT}. Further, the MCP 70 can operate in the buck mode to generate the low-frequency voltage V_{DC} at the battery voltage V_{BAT}, thus making it possible to improve the efficiency of the switcher circuit 66 as well.

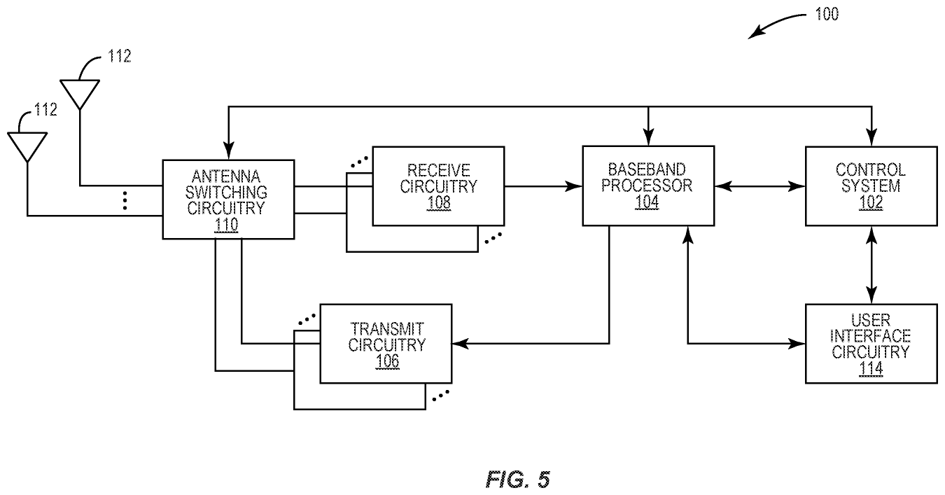

The power management circuit 60 of FIG. 4 can be provided in a user element to enable memory distortion neutralization according to embodiments described above. In this regard, FIG. 5 is a schematic diagram of an exemplary user element 100 wherein the power management circuit 60 of FIG. 4 can be provided.

Herein, the user element 100 can be any type of user elements, such as mobile terminals, smart watches, tablets, computers, navigation devices, access points, and like wireless communication devices that support wireless communications, such as cellular, wireless local area network (WLAN), Bluetooth, and near field communications. The user element 100 will generally include a control system 102, a baseband processor 104, transmit circuitry 106, receive circuitry 108, antenna switching circuitry 110, multiple antennas 112, and user interface circuitry 114. In a non-limiting example, the control system 102 can be a field-programmable gate array (FPGA), as an example. In this regard, the control system 102 can include at least a microprocessor(s), an embedded memory circuit(s), and a communication bus interface(s). The receive circuitry 108 receives radio frequency signals via the antennas 112 and through the antenna switching circuitry 110 from one or more base stations. A low noise amplifier and a filter cooperate to amplify and remove broadband interference from the received signal for processing. Downconversion and digitization circuitry (not shown) will then downconvert the filtered, received signal to an intermediate or baseband frequency signal, which is then digitized into one or more digital streams using analog-to-digital converter(s) (ADC).

The baseband processor 104 processes the digitized received signal to extract the information or data bits conveyed in the received signal. This processing typically comprises demodulation, decoding, and error correction operations, as will be discussed in greater detail below. The baseband processor 104 is generally implemented in one or more digital signal processors (DSPs) and application specific integrated circuits (ASICs).

For transmission, the baseband processor 104 receives digitized data, which may represent voice, data, or control information, from the control system 102, which it encodes for transmission. The encoded data is output to the transmit circuitry 106, where a digital-to-analog converter(s) (DAC) converts the digitally encoded data into an analog signal and a modulator modulates the analog signal onto a carrier signal that is at a desired transmit frequency or frequencies. A power amplifier will amplify the modulated carrier signal to a level appropriate for transmission, and deliver the modulated carrier signal to the antennas 112 through the antenna switching circuitry 110. The multiple antennas 112 and the replicated transmit and receive circuitries 106, 108 may provide spatial diversity. Modulation and processing details will be understood by those skilled in the art.

Those skilled in the art will recognize improvements and modifications to the preferred embodiments of the present disclosure. All such improvements and modifications are considered within the scope of the concepts disclosed herein and the claims that follow.

1. A hybrid power amplifier circuit comprising:
a signal input that receives a radio frequency (RF) signal having a time-variant input power;
a signal output that outputs the RF signal having a time-variant output power to a load circuit having an inherent load impedance;
a carrier amplifier and a peak amplifier coupled in parallel between the signal input and the signal output and configured to collectively amplify the RF signal from the time-variant input power to the time-variant output power based on an envelope tracking (ET) modulated voltage; and
a control circuit configured to bias the peak amplifier based on a reference voltage to present a modulated load impedance to the carrier amplifier to thereby cause the carrier amplifier to operate in compression in response to an average of the ET modulated voltage being substantially equal to the reference voltage.

2. The hybrid power amplifier circuit of claim 1, further comprising an impedance inverter circuit configured to generate the modulated load impedance as a function of an equivalent load impedance of the peak amplifier and the load circuit.

3. The hybrid power amplifier circuit of claim 2, wherein the modulated load impedance is expressed as: Z_{M}=−Kₐ²/Z_{L-EQ}, wherein:
Z_{M} represents the modulated load impedance presented to the carrier amplifier;
Kₐ represents a coefficient of the impedance inverter circuit; and
Z_{L-EQ} represents the equivalent load impedance of the peak amplifier and the load circuit.

4. The hybrid power amplifier circuit of claim 3, wherein the equivalent load impedance of the peak amplifier and the load circuit is expressed as: Z_{L-EQ}=Z_{LOAD}/[1−I_{P}/(2*I_{M})], wherein:
Z_{LOAD} represents the inherent load impedance of the load circuit;
I_{P} represents a time-variant peak current envelope; and
I_{M} represents a time-variant carrier current envelope.

5. The hybrid power amplifier circuit of claim 2, wherein the ET modulated voltage is generated to track a time-variant carrier voltage envelope across the carrier amplifier, wherein the time-variant carrier voltage envelope is a function of the modulated load impedance presented to the carrier amplifier.

6. The hybrid power amplifier circuit of claim 5, wherein the time-variant carrier voltage envelope is expressed as: V_{M}=I_{M}*Z_{M}, wherein:
V_{M} represents the time-variant carrier voltage envelope;
I_{M} represents a time-variant carrier current envelope; and
Z_{M} represents the modulated load impedance presented to the carrier amplifier.

7. The hybrid power amplifier circuit of claim 5, wherein the average of the ET modulated voltage is expressed as: avg(V_{CC})≈avg(V_{M})*TFC, wherein:
avg(V_{CC}) represents the average of the ET modulated voltage;
avg(V_{M}) represents an average of the time-variant carrier voltage envelope; and
TFC represents a carrier load-line transfer function.

8. The hybrid power amplifier circuit of claim 7, wherein the average of the time-variant carrier voltage envelope is expressed as: avg(V_{M})=4*Z_{LOAD}*(avg(I_{M}]−avg(I_{P})/2), wherein:
Z_{LOAD} represents the inherent load impedance of the load circuit;
avg(I_{P}) represents an average of a time-variant peak current envelope; and
avg(I_{M}) represents an average of a time-variant carrier current envelope.

9. The hybrid power amplifier circuit of claim 8, wherein the control circuit is further configured to bias the peak amplifier based on the reference voltage such that the time-variant peak current envelope can be generated to change the average of the time-variant carrier voltage envelope to thereby cause the average of the ET modulated voltage to be substantially equal to the reference voltage.

10. A power management circuit comprising:
an envelope tracking (ET) integrated circuit (ETIC) comprising:
a switcher circuit configured to generate a low-frequency current as a function of a battery voltage; and
a voltage circuit configured to generate an ET modulated voltage based on an ET target voltage and the low-frequency current; and
a hybrid power amplifier circuit comprising:
a signal input that receives a radio frequency (RF) signal having a time-variant input power;
a signal output that outputs the RF signal having a time-variant output power to a load circuit having an inherent load impedance;
a carrier amplifier and a peak amplifier coupled in parallel between the signal input and the signal output and configured to collectively amplify the RF signal from the time-variant input power to the time-variant output power based on the ET modulated voltage; and
a control circuit configured to bias the peak amplifier based on a reference voltage that corresponds to a reading of the battery voltage to present a modulated load impedance to the carrier amplifier to thereby cause the carrier amplifier to operate in compression in response to an average of the ET modulated voltage being substantially equal to the reference voltage.

11. The power management circuit of claim 10, wherein the voltage circuit comprises:
a voltage amplifier configured to generate an initial ET modulated voltage based on an ET target voltage and a supply voltage; and
an offset capacitor configured to raise the initial ET modulated voltage by an offset voltage to generate the ET modulated voltage.

12. The power management circuit of claim 10, wherein the switcher circuit comprises:
a multi-level charge pump, MCP, configured to generate a low-frequency voltage at multiple levels based on the battery voltage; and
a power inductor configured to induce the low-frequency current based on the low-frequency voltage.

13. The power management circuit of claim 10, wherein the hybrid power amplifier circuit further comprises an impedance inverter circuit configured to generate the modulated load impedance as a function of an equivalent load impedance of the peak amplifier and the load circuit.

14. The power management circuit of claim 13, wherein the modulated load impedance is expressed as: Z_{M}=−Kₐ²/Z_{L-EQ}, wherein:
Z_{M} represents the modulated load impedance presented to the carrier amplifier;
Kₐ represents a coefficient of the impedance inverter circuit; and
Z_{L-EQ} represents the equivalent load impedance of the peak amplifier and the load circuit.

15. The power management circuit of claim 14, wherein the equivalent load impedance of the peak amplifier and the load circuit is expressed as: Z_{L-EQ}=Z_{LOAD}/[1−I_{P}/(2*I_{M})], wherein:
Z_{LOAD} represents the inherent load impedance of the load circuit;
I_{P} represents a time-variant peak current envelope; and
I_{M} represents a time-variant carrier current envelope.

16. The power management circuit of claim 13, wherein the ET modulated voltage is generated to track a time-variant carrier voltage envelope across the carrier amplifier, wherein the time-variant carrier voltage envelope is a function of the modulated load impedance presented to the carrier amplifier.

17. The power management circuit of claim 16, wherein the time-variant carrier voltage envelope is expressed as: V_{M}=I_{M}*Z_{M}, wherein:
V_{M} represents the time-variant carrier voltage envelope;
I_{M} represents a time-variant carrier current envelope; and
Z_{M} represents the modulated load impedance presented to the carrier amplifier.

18. The power management circuit of claim 16, wherein the average of the ET modulated voltage is expressed as: avg(V_{CC})≈avg(V_{M})*TFC, wherein:
avg(V_{CC}) represents the average of the ET modulated voltage;
avg(V_{M}) represents an average of the time-variant carrier voltage envelope; and
TFC represents a carrier load-line transfer function.

19. The power management circuit of claim 18, wherein the average of the time-variant carrier voltage envelope is expressed as: avg(V_{M})=4*Z_{LOAD}*(avg(I_{M})−avg(I_{P})/2), wherein:
Z_{LOAD} represents the inherent load impedance of the load circuit;
avg(I_{P}) represents an average of a time-variant peak current envelope; and
avg(I_{M}) represents an average of a time-variant carrier current envelope.

20. The power management circuit of claim 19, wherein the control circuit is further configured to bias the peak amplifier based on the reference voltage such that the time-variant peak current envelope can be generated to change the average of the time-variant carrier voltage envelope to thereby cause the average of the ET modulated voltage to be substantially equal to the reference voltage.
